(19) United States
(12) Patent Application Publication
(10) Pub. No.: US 2025/0087590 A1
(43) Pub. Date: Mar. 13, 2025

(54) SEMICONDUCTOR DEVICE

(71) Applicant: SHINKO ELECTRIC INDUSTRIES CO., LTD., Nagano-shi (JP)

(72) Inventor: Hisashi KANEDA, Nagano-shi (JP)

(21) Appl. No.: 18/824,234

(22) Filed: Sep. 4, 2024

(30) Foreign Application Priority Data
Sep. 8, 2023 (JP) 2023-146257

(51) Int. Cl. H01L 23/538; H01L 23/00; H01L 23/13; H01L 23/36; H01L 25/16

(52) U.S. Cl. CPC H01L 23/5385; H01L 23/13; H01L 23/36; H01L 25/167; H01L 24/16; H01L 2224/16227

(57) ABSTRACT

A semiconductor device includes a first substrate, a second substrate spaced apart from the first substrate, a first semiconductor element mounted on an upper surface of the first substrate and an upper surface of the second substrate so as to extend across the first substrate and the second substrate, a second semiconductor element mounted on the upper surface of the second substrate, and a third semiconductor element mounted on a lower surface of the second substrate. The third semiconductor element overlaps the second semiconductor element in plan view.

### CROSS-REFERENCE TO RELATED APPLICATIONS

This application is based upon and claims the benefit of priority from prior Japanese Patent Application No. 2023-146257, filed on Sep. 8, 2023, the entire contents of which are incorporated herein by reference.

### BACKGROUND

### 1. Field

The following disclosure relates to a semiconductor device.

### 2. Description of Related Art

Japanese Laid-Open Patent Publication No. 2020-107681 discloses a semiconductor device including semiconductor elements mounted on a substrate. In the conventional semiconductor device, the semiconductor elements are arranged next to one another on the substrate. This enlarges the semiconductor device in plan view.

### SUMMARY

In one general aspect, a semiconductor device includes a first substrate, a second substrate spaced apart from the first substrate, a first semiconductor element mounted on an upper surface of the first substrate and an upper surface of the second substrate so as to extend across the first substrate and the second substrate, a second semiconductor element mounted on the upper surface of the second substrate, and a third semiconductor element mounted on a lower surface of the second substrate. The third semiconductor element overlaps the second semiconductor element in plan view.

Other features and aspects will be apparent from the following detailed description, the drawings, and the claims.

### BRIEF DESCRIPTION OF THE DRAWINGS

FIG. 1 is a schematic cross-sectional view illustrating a first embodiment of a semiconductor device taken along line 1-1 in FIG. 2.

FIG. 2 is a schematic top view illustrating an upper surface of the semiconductor device of FIG. 1.

FIG. 3 is a schematic bottom view illustrating a lower surface of the semiconductor device of FIG. 1.

FIGS. 4, 5, and 6 are schematic cross-sectional views illustrating a method for manufacturing the semiconductor device of FIG. 1.

FIG. 7 is a schematic cross-sectional view illustrating a second embodiment of a semiconductor device.

FIG. 8 is a schematic cross-sectional view illustrating a modified example of a semiconductor device.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Embodiments will now be described with reference to the drawings. In the accompanying drawings, elements are illustrated for simplicity and clarity and have not necessarily been drawn to scale. To facilitate understanding, hatching lines may be replaced by shadings or may not be illustrated in the cross-sectional views. Each drawing indicates an X-axis, a Y-axis, and a Z-axis, which are orthogonal to each other. In the description hereafter, the direction extending along the X-axis will be referred to as the X-axis direction, the direction extending along the Y-axis will be referred to as the Y-axis direction, and the direction extending along the Z-axis will be referred to as the Z-axis direction. In this specification, “plan view” refers to a view of a subject taken in the Z-axis direction unless otherwise specified. Further, in this specification, “planar shape” refers to a shape of a subject as viewed in the Z-axis direction unless otherwise specified. In this specification, “the same” will not only cover a state in which the compared subjects are exactly the same but also cover a state in which there is a slight difference, resulting from dimensional tolerances or the like, between the compared subjects.

### First Embodiment

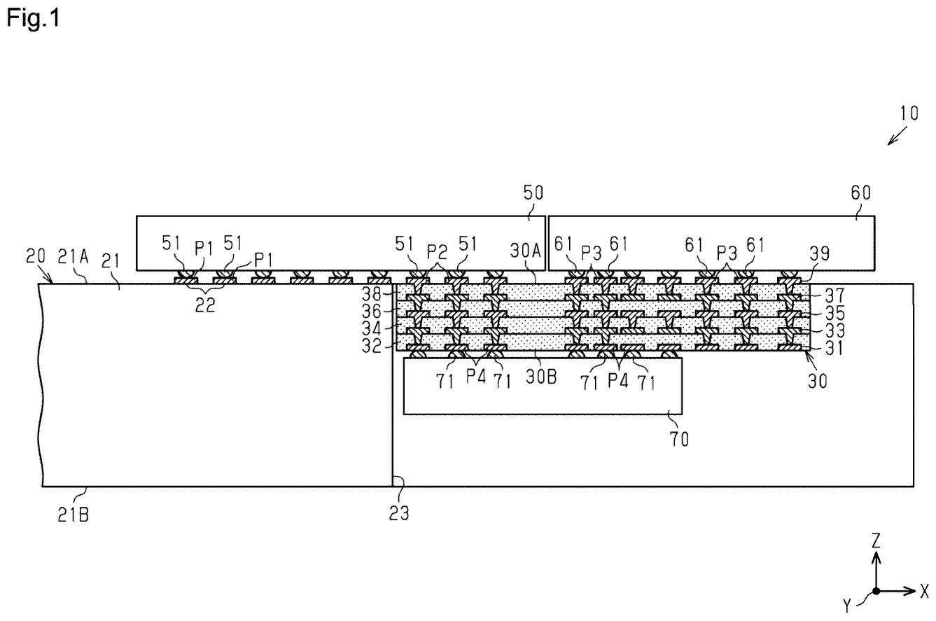

A first embodiment will now be described with reference to FIGS. 1 to 6.

### Overall Structure of Semiconductor Device 10

As illustrated in FIG. 1, a semiconductor device 10 includes a first substrate 20, a second substrate 30, a first semiconductor element 50, a second semiconductor element 60, and a third semiconductor element 70. In the present specification, the side where the first semiconductor element 50 and the second semiconductor element 60 are located in the Z-axis direction will be referred to as the upper side, and the side where the third semiconductor element 70 is located in the Z-axis direction will be referred to as the lower side. The semiconductor device 10 may, however, be manufactured and used in a reversed state so as to be upside down, and be manufactured and used in a state oriented in any direction.

The first semiconductor element 50 is mounted on an upper surface 21A of the first substrate 20 and an upper surface 30A of the second substrate 30 so as to extend across the first substrate 20 and the second substrate 30. The second semiconductor element 60 is mounted on the upper surface 30A of the second substrate 30. The third semiconductor element 70 is mounted on a lower surface 30B of the second substrate 30 at an opposite side of the upper surface 30A, which is where the first semiconductor element 50 and the second semiconductor element 60 are mounted.

The semiconductor device 10 is, for example, an optical semiconductor device used for optical communication or the like. In the first embodiment, the semiconductor device 10 is an optical semiconductor device including a photonic integrated circuit (PIC) and an electrical integrated circuit (EIC).

The second semiconductor element 60 is, for example, a photonic IC including an optical circuit. The photonic IC may be, for example, a silicon photonics chip. An optical circuit of the second semiconductor element 60 includes, for example, a photodetector and an optical modulator. The third semiconductor element 70 is, for example, an electrical IC including an electrical circuit. The electrical circuit of the third semiconductor element 70 includes, for example, a drive circuit that drives an optical modulator of an optical circuit. The third semiconductor element 70 of the present example, is an electrical IC for driving an optical circuit. The electrical circuit of the third semiconductor element 70 may include an amplification circuit that amplifies signals from a photodetector. The first semiconductor element 50 is, for example, an electrical IC including an electrical circuit. The first semiconductor element 50 is, for example, a large scale integration (LSI) chip incorporating a digital signal processor (DSP) and an amplifier that process signals from a photodetector. Thus, the first semiconductor element 50 is an LSI including an electrical circuit for processing signals. The first semiconductor element 50, for example, generates more heat than the second semiconductor element 60. The first semiconductor element 50, for example, generates more heat than the third semiconductor element 70.

### Structure of First Substrate 20

The first substrate 20 includes a substrate body 21, which has the upper surface 21A and a lower surface 21B at an opposite side of the upper surface 21A, and a wiring layer 22, which is arranged on the upper surface 21A of the substrate body 21. The first semiconductor element 50 is mounted on the first substrate 20. An optical functional element or electronic component other than the first semiconductor element 50, the second semiconductor element 60, and the third semiconductor element 70 may be mounted on the first substrate 20. Examples of an optical functional element include, for example, a light emitting element, a light receiving element, an optical amplifier, and an optical attenuator. Examples of the electronic components include a crystal oscillator or a chip component, such as a chip capacitor, a chip resistor, and a chip inductor. The first substrate 20 is, for example, a wiring substrate including wiring (wiring layer 22) electrically connected to electronic components and the like mounted on the first substrate 20.

The substrate body 21 may be a wiring structure with alternately stacked insulation resin layers and wiring layers. The wiring structure may, for example, include a cored substrate but does not have to include a cored substrate. The material of the insulation resin layers may be, for example, an insulative thermosetting resin. The insulative thermosetting resin may be, for example, an insulative resin such as an epoxy resin, a polyimide resin, or a cyanate resin. The material of the insulative resin layers may also be, for example, an insulative resin of which the main component is a photosensitive resin such as a phenolic resin or a polyimide resin. The insulative resin layers may include, for example, a filler such as silica (SiO₂) or alumina (Al₂O₃).

The substrate body 21 has, for example, a greater thickness than the second substrate 30. The thickness of the substrate body 21 is, for example, greater than the sum of the thickness of the second substrate 30 and the thickness of the third semiconductor element 70. The thickness of the substrate body 21 may be, for example, about 400 μm to 1500 μm.

The wiring layer 22 is arranged on the upper surface 21A of the substrate body 21 that is a mounting surface on which the first semiconductor element 50 is mounted. The wiring layer 22 is, for example, electrically connected to a wiring layer (not illustrated) that is located on the lower surface 21B of the substrate body 21 by a wiring layer and a through electrode in the substrate body 21. The wiring layer 22 includes first connection pads P1 electrically connected to the first semiconductor element 50. The wiring layer 22 may have a thickness of, for example, about 10 μm to 20 μm. The material of the wiring layer 22 may be, for example, copper (Cu) or a copper alloy.

A surface-processed layer may be formed on the surface (upper and side surfaces or only upper surface) of each first connection pad P1 when necessary. Examples of the surface-processed layer includes a gold (Au) layer, a nickel (Ni) layer/Au layer (metal layer in which Ni layer serves as bottom layer, and Au layer is formed on Ni layer), Ni layer/palladium (Pd) layer/Au layer (metal layer in which Ni layer serves as bottom layer, and Ni layer and Pd layer are sequentially formed on Au layer). Further examples of the surface-processed layer include Ni layer/Pd layer (metal layer in which Ni layer serves as bottom layer, and Pd layer is formed on Ni layer), Pd layer/Au layer (metal layer in which Pd layer serves as bottom layer, and Au layer is formed on Pd layer). An Au layer is a metal layer formed from Au or an Au alloy, a Ni layer is a metal layer formed from Ni or a Ni alloy, and a Pd layer is a metal layer formed from Pd or a Pd alloy. An Au layer, a Ni layer, and a Pd layer may each be, for example, a metal layer formed through an electroless plating process (electroless plating metal layer) or a metal layer formed through an electrolytic plating process (electrolytic plating metal layer). Further, the surface-processed layer may be an organic solderability preservative (OSP) film formed on the surface of each first connection pad P1 through an anti-oxidation process such as an OSP process. The OSP film may be an organic coating of an azole compound or an imidazole compound.

The first substrate 20 includes a through hole 23 extending through the substrate body 21 in a thickness direction (Z-axis direction). The through hole 23 extends through the substrate body 21 from the upper surface 21A to the lower surface 21B of the substrate body 21. The through hole 23 is large enough to accommodate the second substrate 30 and the third semiconductor element 70, which is mounted on the lower surface 30B of the second substrate 30.

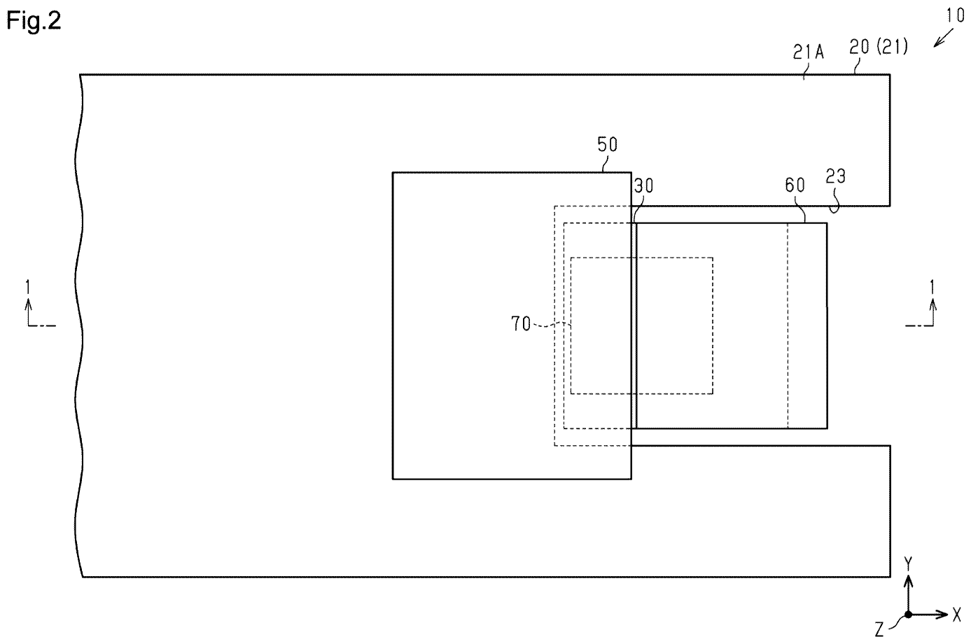

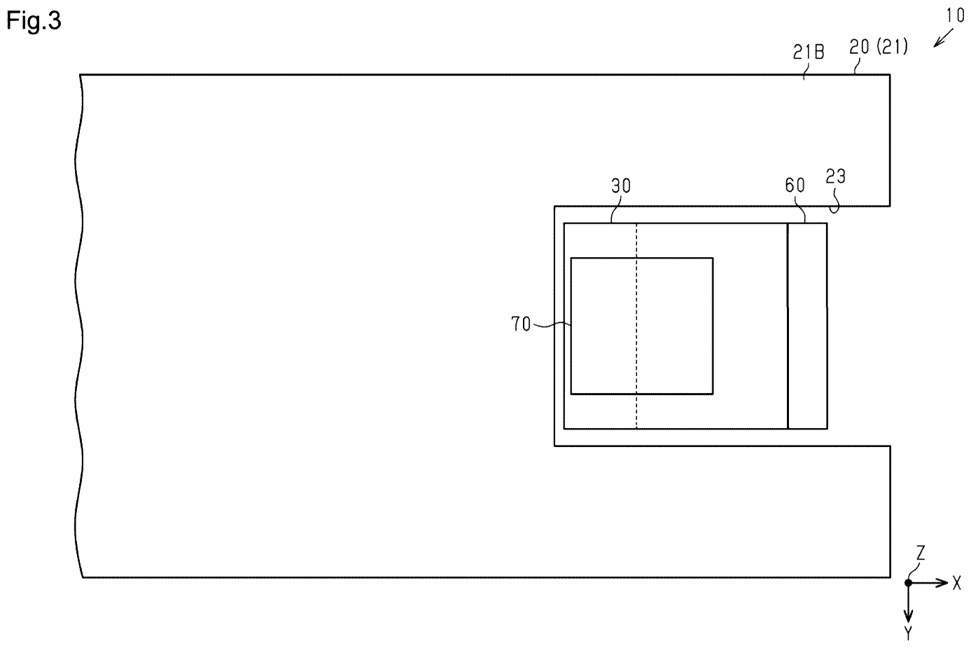

As illustrated in FIGS. 2 and 3, the planar shape of the through hole 23 may be similar to, for example, the planar shape of the second substrate 30. For example, the through hole 23 has a rectangular planar shape. The through hole 23 is larger in size than the second substrate 30 in plan view. The planar size of the through hole 23 is set to allow the second substrate 30 to be entirely accommodated therein. For example, the through hole 23 is larger in size than the second semiconductor element 60 in plan view.

The through hole 23 is, for example, a notch. The through hole 23 is recessed from an end surface of the substrate body 21 in the X-axis direction toward the inner side of the substrate body 21. The through hole 23 opens in this end surface of the substrate body 21 in the X-axis direction. The through hole 23 is located in, for example, a middle part of the substrate body 21 in the Y-axis direction.

### Structure of Second Substrate 30

The second substrate 30 is a substrate separate from the first substrate 20. The second substrate 30 is spaced apart from the first substrate 20. The second substrate 30 does not overlap the first substrate 20 in plan view. The second substrate 30 is arranged inside the through hole 23. For example, the second substrate 30 is arranged inside the through hole 23 in a state spaced apart from every inner wall surface of the through hole 23. Thus, a gap is formed between the side surface of the second substrate 30 and the inner wall surface of the through hole 23.

As illustrated in FIG. 1, the second substrate 30 includes the upper surface 30A and the lower surface 30B, which is located at an opposite side of the upper surface 30A. The upper surface 30A is, for example, coplanar with the upper surface 21A of the first substrate 20. The lower surface 30B is, for example, located upward from the lower surface 21B of the first substrate 20.

The second substrate 30 includes second connection pads P2 electrically connected to the first semiconductor element 50, third connection pads P3 electrically connected to the second semiconductor element 60, and fourth connection pads P4 electrically connected to the third semiconductor element 70.

The second substrate 30 is a multilayer wiring substrate having a structure in which wiring layers and insulation layers are alternately stacked one upon another. The second substrate 30 has a structure obtained by sequentially stacking a wiring layer 31, an insulation layer 32, a wiring layer 33, an insulation layer 34, a wiring layer 35, an insulation layer 36, a wiring layer 37, an insulation layer 38, and a wiring layer 39. The second substrate 30 of the present embodiment is a coreless substrate that does not include a support base and thus differs from a wiring substrate manufactured through a typical build-up process, that is, a wiring substrate formed by sequentially stacking a given number of build-up layers on one side or two opposite sides of a core substrate serving as a support base.

The material of the wiring layers 31, 33, 35, 37, and 39 may be, for example, copper or copper alloy. The wiring layers 31, 33, 35, 37, and 39 may each have a thickness of, for example, about 10 μm to 20 μm. The line-and-space (L/S) of the wiring layers 31, 33, 35, 37, and 39 may be, for example, about 10 μm/10 μm to 20 μm/20 μm. The line in the line-and-space (L/S) indicates the width of wiring, and the space in the line-and-space (L/S) indicates the distance between adjacent wirings. For example, when L/S is described as being 20 μm/20 μm, the distance between adjacent wirings, each having a wiring width of 20 μm, will be 20 μm.

The material of the insulation layers 32, 34, 36, and 38 may be, for example, an insulative resin of which the main component is a photosensitive resin such as a phenolic resin or a polyimide resin. The insulation layers 32, 34, 36, and 38 may contain, for example, a filler of silica or alumina. Further, the material of the insulation layers 32, 34, 36, and 38 may be, for example, an insulative resin including a reinforcement material and formed by impregnating a woven or non-woven cloth of glass fibers, aramid fibers, or liquid crystal polymer (LCP) fibers with an epoxy resin or a polyimide thermosetting insulative resin. The insulation layers 32, 34, 36, and 38 may each have a thickness of, for example, about 20 μm to 45 μm.

The wiring layer 31 is the outermost wiring layer (here, lowermost wiring layer) of the second substrate 30. The lower surface of the wiring layer 31 is exposed from the lower surface of the insulation layer 32, that is, the lower surface 30B of the second substrate 30. The lower surface of the wiring layer 31 is, for example, flush with the lower surface of the insulation layer 32. The wiring layer 31 includes the fourth connection pads P4, which are electrically connected to the third semiconductor element 70. That is, the fourth connection pads P4 are arranged on the lower surface 30B of the second substrate 30.

A surface-processed layer may be formed on the surface (here, lower surface) of each fourth connection pad P4 when necessary. Examples of the surface-processed layer include an OSP film or a metal layer such as a Au layer, a Ni layer/Au layer, a Ni layer/Pd layer/Au layer, a Ni layer/Pd layer, or a Pd layer/Au layer.

The insulation layer 32 is the outermost insulation layer (here, lowermost insulation layer) of the second substrate 30. The insulation layer 32 covers the upper surface and side surfaces of the wiring layer 31 and exposes the lower surface of the wiring layer 31. The lower surface of the insulation layer 32 is the lower surface 30B of the second substrate 30.

The wiring layer 33 is formed on the upper surface of the insulation layer 32. The wiring layer 33 is, for example, formed integrally with via wiring extending through the insulation layer 32 in the thickness direction. The via wiring is electrically connected to the wiring layer 31. The insulation layer 34 is formed on the upper surface of the insulation layer 32 and covers the wiring layer 33. The wiring layer 35 is formed on the upper surface of the insulation layer 34. The wiring layer 35 is, for example, formed integrally with via wiring extending through the insulation layer 34 in the thickness direction. The via wiring is electrically connected to the wiring layer 33. The insulation layer 36 is formed on the upper surface of the insulation layer 34 and covers the wiring layer 35. The wiring layer 37 is formed on the upper surface of the insulation layer 36. The wiring layer 37 is, for example, formed integrally with via wiring extending through the insulation layer 36 in the thickness direction. The via wiring is electrically connected to the wiring layer 35. The insulation layer 38 is formed on the upper surface of the insulation layer 36 and covers the wiring layer 37. The insulation layer 38 is the outermost insulation layer (here, uppermost insulation layer) of the second substrate 30. The upper surface of the insulation layer 38 is the upper surface 30A of the second substrate 30. The upper surface of the insulation layer 38 is coplanar with the upper surface 21A of the substrate body 21.

The wiring layer 39 is the outermost wiring layer (here, uppermost wiring layer) of the second substrate 30. The wiring layer 39 is formed on the upper surface of the insulation layer 38, that is, the upper surface 30A of the second substrate 30. The wiring layer 39 is, for example, formed integrally with via wiring extending through the insulation layer 38 in the thickness direction. The via wiring is electrically connected to the wiring layer 37. The wiring layer 39 includes the second connection pads P2, which are electrically connected to the first semiconductor element 50, and the third connection pads P3, which are electrically connected to the second semiconductor element 60. That is, the second connection pads P2 and the third connection pads P3 are arranged on the upper surface 30A of the second substrate 30. In other words, the second connection pads P2 are located on the same plane as the third connection pads P3.

A surface-processed layer may be formed on the surface (here, upper surface and side surface or only upper surface) of each second connection pad P2 and each third connection pad P3 when necessary. Examples of the surface-processed layer include an OSP film or a metal layer such as a Au layer, a Ni layer/Au layer, a Ni layer/Pd layer/Au layer, a Ni layer/Pd layer, or a Pd layer/Au layer.

### Structure of First Semiconductor Element 50

The first semiconductor element 50 includes, for example, bumps 51 formed on a circuit formation surface (in this case, lower surface) of the first semiconductor element 50. The first semiconductor element 50 is mounted on the upper surface 21A of the first substrate 20 and the upper surface 30A of the second substrate 30 so as to extend across a gap formed between the first substrate 20 and the second substrate 30. The first semiconductor element 50 is flip-chip mounted on the upper surface 21A of the first substrate 20 and flip-chip mounted on the upper surface 30A of the second substrate 30. The first semiconductor element 50 is electrically connected by the bumps 51 to the first connection pads P1 of the first substrate 20 and the second connection pads P2 of the second substrate 30. Thus, the first semiconductor element 50 is electrically connected by the bumps 51 to the wiring layer 22 of the first substrate 20 and electrically connected by the bumps 51 to the wiring layer 39 of the second substrate 30, The first semiconductor element 50 connects the first substrate 20 and the second substrate 30 to each other. In other words, the first semiconductor element 50 is mounted on the first substrate 20 and the second substrate 30 so as to connect the first substrate 20 and the second substrate 30.

The bumps 51 may be, for example, gold bumps or solder bumps. The material of the solder bumps may be, for example, an alloy including Pb, an alloy of Sn and Au, an alloy of Sn and Cu, an alloy of Sn and Ag, or an alloy of Sn, Ag, and Cu.

As illustrated in FIG. 2, the first semiconductor element 50 is, for example, larger in size than the second semiconductor element 60 in plan view. The first semiconductor element 50 is, for example, larger in size than the third semiconductor element 70 in plan view. The dimension of the first semiconductor element 50 in the Y-axis direction is, for example, greater than the dimension of the third semiconductor element 70 in the Y-axis direction. The dimension of the first semiconductor element 50 in the Y-axis direction is, for example, greater than the dimension of the second semiconductor element 60 in the Y-axis direction. The dimension of the first semiconductor element 50 in the Y-axis direction is, for example, greater than the dimension of the second semiconductor substrate 30 in the Y-axis direction. The dimension of the first semiconductor element 50 in the Y-axis direction is, for example, greater than the dimension of the through hole 23 in the Y-axis direction.

### Structure of Second Semiconductor Element 60

As illustrated in FIG. 1, the second semiconductor element 60 includes, for example, bumps 61 formed on a circuit formation surface (in this case, lower surface) of the second semiconductor element 60. The second semiconductor element 60 is mounted on the upper surface 30A of the second substrate 30. The second semiconductor element 60 is flip-chip mounted on the upper surface 30A of the second substrate 30. The second semiconductor element 60 is electrically connected by the bumps 61 to the third connection pads P3 of the second substrate 30. Thus, the second semiconductor element 60 is electrically connected by the bumps 61 to the wiring layer 39 of the second substrate 30.

The bumps 61 may be, for example, gold bumps or solder bumps. The material of the solder bumps may be, for example, an alloy including Pb, an alloy of Sn and Au, an alloy of Sn and Cu, an alloy of Sn and Ag, or an alloy of Sn, Ag, and Cu.

The second semiconductor element 60 is, for example, located on the same plane as the first semiconductor element 50. The second semiconductor element 60 is located proximate to the first semiconductor element 50. The second semiconductor element 60 is located proximate to the first semiconductor element 50 in, for example, the X-axis direction. For example, the distance between the first semiconductor element 50 and the second semiconductor element 60 in the X-axis direction is less than the distance between the wall surface of the through hole 23 and the side surface of the second substrate 30 in the X-axis direction.

As illustrated in FIG. 2, the second semiconductor element 60 is, for example, larger in size than the third semiconductor element 70 in plan view. The dimension of the second semiconductor element 60 in the Y-axis direction is, for example, greater than the dimension of the third semiconductor element 70 in the Y-axis direction. The dimension of the second semiconductor element 60 in the Y-axis direction is equal to the dimension of the second semiconductor substrate 30 in the Y-axis direction. The side surfaces of the second semiconductor element 60 in the Y-axis direction are, for example, coplanar with the side walls of the second substrate 30 in the Y-axis direction. The one end (right end in FIG. 2) of the second semiconductor element 60 in the X-axis direction projects in the X-axis direction (right direction in FIG. 2) from, for example, the end surface (right end surface in FIG. 2) of the second substrate 30 in the X-axis direction. In other words, the right end of the second semiconductor element 60 in the X-axis direction does not overlap the second substrate 30 in plan view. Such an end of the second semiconductor element 60 in the X-axis direction is, for example, optically coupled to a light transmission path such as an optical fiber (not illustrated).

As illustrated in FIG. 2, the second substrate 30 includes a first end surface (left end surface in FIG. 2) facing the wall surface of the through hole 23 in the X-axis direction and a second end surface (right end surface in FIG. 2) at an opposite side of the first end surface. The first end surface (i.e., left end surface) of the second substrate 30 overlaps the first semiconductor element 50 in plan view. The second end surface (i.e., right end surface) of the second substrate 30 overlaps the second semiconductor element 60 in plan view. In this example, the first semiconductor element 50 projects outward from the first end surface of the second substrate 30 in the X-axis direction, and the second semiconductor element 60 projects outward from the second end surface of the second substrate 30 in the X-axis direction. The dimension of the second substrate 30 in the X-axis direction is less than a total of the dimension of the first semiconductor element 50 in the X-axis direction and the dimension of the second semiconductor element 60 in the X-axis direction.

### Structure of Third Semiconductor Element 70

As illustrated in FIG. 1, the third semiconductor element 70 includes bumps 71 formed on a circuit formation surface (in this case, upper surface) of the third semiconductor element 70. The third semiconductor element 70 is mounted on the lower surface 30B of the second substrate 30. The third semiconductor element 70 is flip-chip mounted on the lower surface 30B of the second substrate 30. The third semiconductor element 70 is electrically connected by the bumps 71 to the fourth connection pads P4 of the second substrate 30. Thus, the third semiconductor element 70 is electrically connected by the bumps 71 to the wiring layer 31 of the second substrate 30. The third semiconductor element 70 is electrically connected by the wiring layers 31, 33, 35, 37, and 39 to the first semiconductor element 50. The third semiconductor element 70 is electrically connected by the wiring layers 31, 33, 35, 37, and 39 to the second semiconductor element 60.

The bumps 71 may be, for example, gold bumps or solder bumps. The material of the solder bumps may be, for example, an alloy including Pb, an alloy of Sn and Au, an alloy of Sn and Cu, an alloy of Sn and Ag, or an alloy of Sn, Ag, and Cu.

As illustrated in FIG. 2, the third semiconductor element 70 overlaps the second semiconductor element 60 in plan view. The third semiconductor element 70 partially overlaps the second semiconductor element 60 in plan view. The third semiconductor element 70, for example, overlaps the first semiconductor element 50 in plan view. The third semiconductor element 70, for example, partially overlaps the first semiconductor element 50 in plan view. The third semiconductor element 70 extends across the first semiconductor element 50 and the second semiconductor element 60. The third semiconductor element 70 does not overlap the first substrate 20 in plan view.

### Method for Manufacturing Semiconductor Device 10

One example of a method for manufacturing the semiconductor device 10 will now be described. To simplify illustration, elements that will consequently become the final elements of the semiconductor device 10 are given the same reference characters as the final elements.

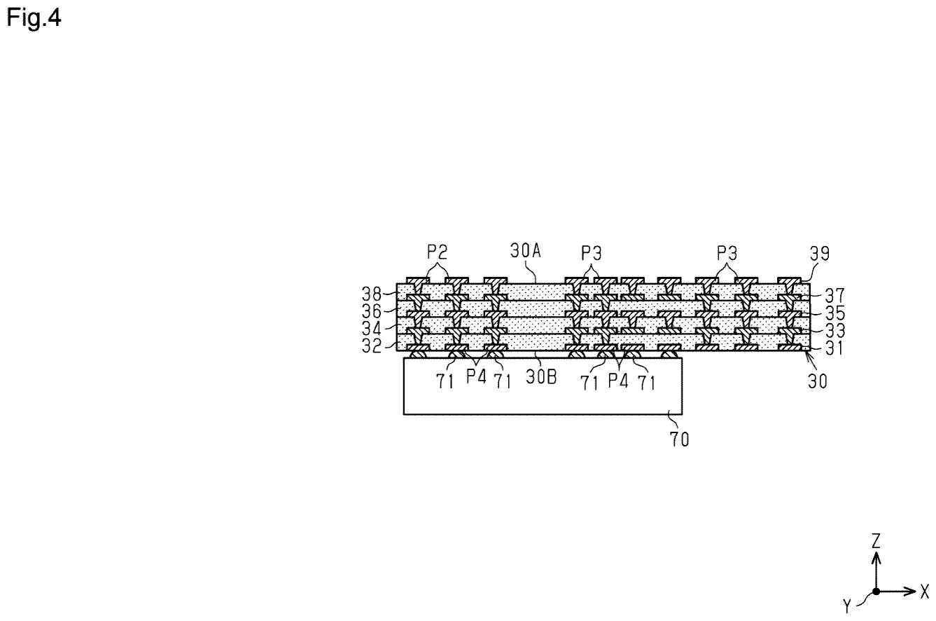

In the step of FIG. 4, the second substrate 30 is first prepared, which includes the wiring layer 31, the insulation layer 32, the wiring layer 33, the insulation layer 34, the wiring layer 35, the insulation layer 36, the wiring layer 37, the insulation layer 38, and the wiring layer 39 that are sequentially stacked. The second substrate 30 is manufactured through a known process. Thus, the process will not be described in detail.

Then, the third semiconductor element 70 is mounted on the lower surface 30B of the second substrate 30. In this example, the bumps 71 of the third semiconductor element 70 are flip-chip bonded to the fourth connection pads P4, which are arranged on the lower surface 30B of the second substrate 30.

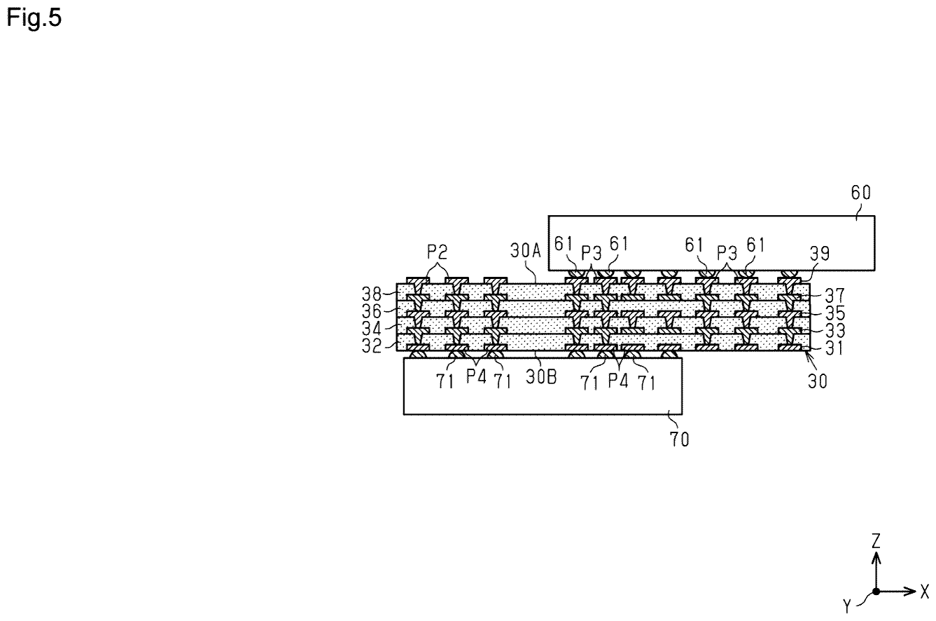

In the step of FIG. 5, the second semiconductor element 60 is mounted on the upper surface 30A of the second substrate 30. In this example, the bumps 61 of the second semiconductor element 60 are flip-chip bonded to the third connection pads P3, which are arranged on the upper surface 30A of the second substrate 30.

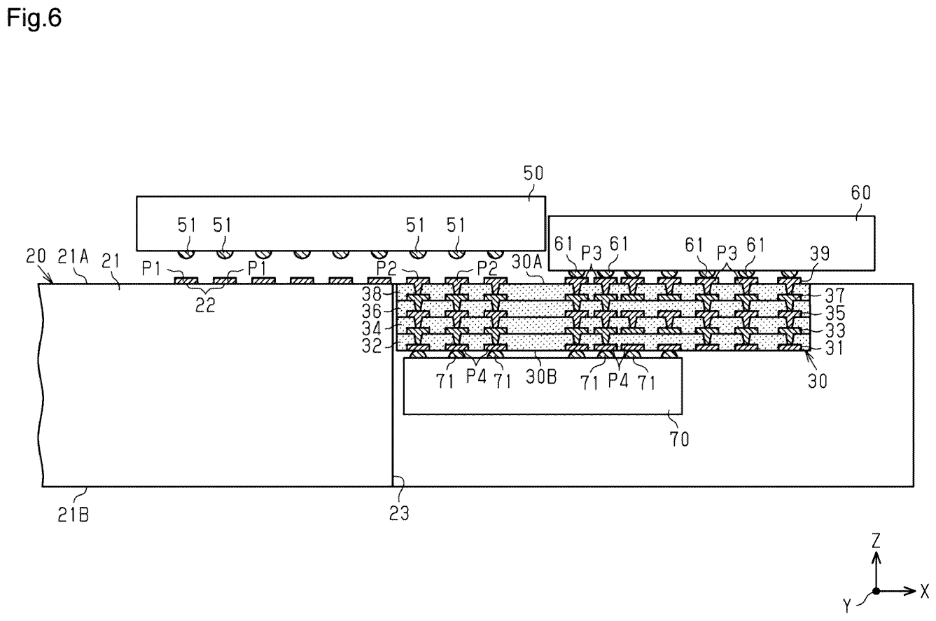

Then, in the step of FIG. 6, the first substrate 20, which includes the through hole 23, is prepared. The second substrate 30, on which the second semiconductor element 60 and the third semiconductor element 70 are mounted, is arranged inside the through hole 23 of the first substrate 20. The second substrate 30 is arranged in the through hole 23 so that, for example, the upper surface 30A of the second substrate 30 is coplanar with the upper surface 21A of the first substrate 20.

Further, the first semiconductor element 50 is mounted on the upper surface 21A of the first substrate 20 and the upper surface 30A of the second substrate 30. In this example, the bumps 51 of the first semiconductor element 50 are flip-chip bonded to the first connection pads P1, which are arranged on the upper surface 21A of the first substrate 20, and the second connection pads P2, which are arranged on the upper surface 30A of the second substrate 30. The semiconductor device 10 illustrated in FIG. 1 is manufactured through the steps described above.

The first embodiment has the advantages described below.

(1-1) The first semiconductor element 50 is mounted on the upper surface 21A of the first substrate 20 and the upper surface 30A of the second substrate 30 so as to extend across the first substrate 20 and the second substrate 30. Further, the second semiconductor element 60 is mounted on the upper surface 30A of the second substrate 30, and the third semiconductor element 70 is mounted on the lower surface 30B of the second substrate 30. The third semiconductor element 70 overlaps the second semiconductor element 60 in plan view. In this structure, the third semiconductor element 70 is mounted on the part of the lower surface 30B of the second substrate 30 overlapping the second semiconductor element 60 in plan view. This allows the second semiconductor element 60 and the third semiconductor element 70 to be mounted, in a state overlapping each other, on the upper surface 30A and the lower surface 30B of the second substrate 30. Thus, the semiconductor device 10 is smaller in planar size than the conventional semiconductor device that mounts three semiconductor elements next to one another on a single substrate.

(1-2) There may be a structure in which three semiconductor elements are arranged on a single substrate. For example, two semiconductor elements may be mounted on the upper surface of the substrate, and one semiconductor element may be mounted on the lower surface of the substrate. In such a structure, however, the thickness of the single substrate will impose limitations on the distance between the semiconductor elements mounted on the upper surface of the substrate and the semiconductor element mounted on the lower surface of the substrate. For example, when the single substrate is thick, the distance will increase between the semiconductor elements mounted on the upper and lower surfaces of the substrate.

In this regard, in the semiconductor device 10 of the present embodiment, three semiconductor elements, namely, the first semiconductor element 50, the second semiconductor element 60, and the third semiconductor element 70 are mounted on the first substrate 20 and the second substrate 30, which is spaced apart from the first substrate 20. In this structure, the first substrate 20 and the second substrate 30 are independent from each other. Thus, even when the first substrate 20 is thick, the second substrate 30 may be decreased in thickness to shorten the distance between the second semiconductor element 60, which is mounted on the upper surface 30A of the second substrate 30, and the third semiconductor element 70, which is mounted on the lower surface 30B of the second substrate 30. This allows the wiring length to be shortened between the second semiconductor element 60 and the third semiconductor element 70 even when the first substrate 20 is thick. Thus, the electrical characteristics of the semiconductor device 10 may be improved.

(1-3) Since the first substrate 20 and the second substrate 30 are independent from each other, compared to when three semiconductor elements are mounted on a single substrate, the semiconductor device 10 has a higher degree of design freedom. In particular, the first substrate 20 and the second substrate 30 have a higher degree of design freedom. For example, the thickness of each wiring layer and each insulation layer in the first substrate 20 may be set to differ from the thickness of each of the wiring layers 31, 33, 35, 37, and 39 and the insulation layers 32, 34, 36, and 38 in the second substrate 30.

(1-4) The third semiconductor element 70 overlaps the first semiconductor element 50 in plan view. In this structure, the third semiconductor element 70 is mounted on the lower surface 30B of the second substrate 30 so as to extend across the first semiconductor element 50 and the second semiconductor element 60. This allows for mounting of the first substrate 20 and the second substrate 30 in a state where the three semiconductor elements, namely, the first semiconductor element 50, the second semiconductor element 60, and the third semiconductor element 70, are proximate to one another. Thus, the semiconductor device 10 is smaller in planar size than the conventional semiconductor device that mounts three semiconductor elements next to one another on a single substrate.

(1-5) The second substrate 30 is arranged inside the through hole 23 that extends through the first substrate 20 in the thickness direction. In this structure, the second substrate 30 does not overlap the first substrate 20 in plan view. This allows the third semiconductor element 70 to be mounted on the lower surface 30B of the second substrate 30 without overlapping the first substrate 20 in plan view. Thus, another component such as a heatsink may be mounted on the lower surface of the third semiconductor element 70. This allows the semiconductor device 10 to have a higher degree of design freedom in comparison with, for example, when the third semiconductor element 70 is incorporated in the first substrate 20.

(1-6) The through hole 23 allows the second substrate 30 to be arranged without extending outward from the side surface of the first substrate 20. This allows for reduction in the planar size of the semiconductor device 10.

(1-7) The through hole 23 is a notch. In the semiconductor device 10 of the present embodiment, the through hole 23 opens in the X-axis direction. Thus, when connecting another member such as an optical fiber to the end of the second semiconductor element 60 in the X-axis direction, interference between the other member and the first substrate 20 will not occur.

(1-8) The thickness of the first substrate 20 is greater than the sum of the thickness of the second substrate 30 and the thickness of the third semiconductor element 70. In this structure, the first substrate 20 is relatively thick, and the second substrate 30 is relatively thin. Thus, even when the first substrate 20 is thick, the distance may be shortened between the second semiconductor element 60, which is mounted on the upper surface 30A of the second substrate 30, and the third semiconductor element 70, which is mounted on the lower surface 30B of the second substrate 30. This allows the wiring length to be shortened between the second semiconductor element 60 and the third semiconductor element 70. Thus, the electrical characteristics of the semiconductor device 10 may be improved.

### Second Embodiment

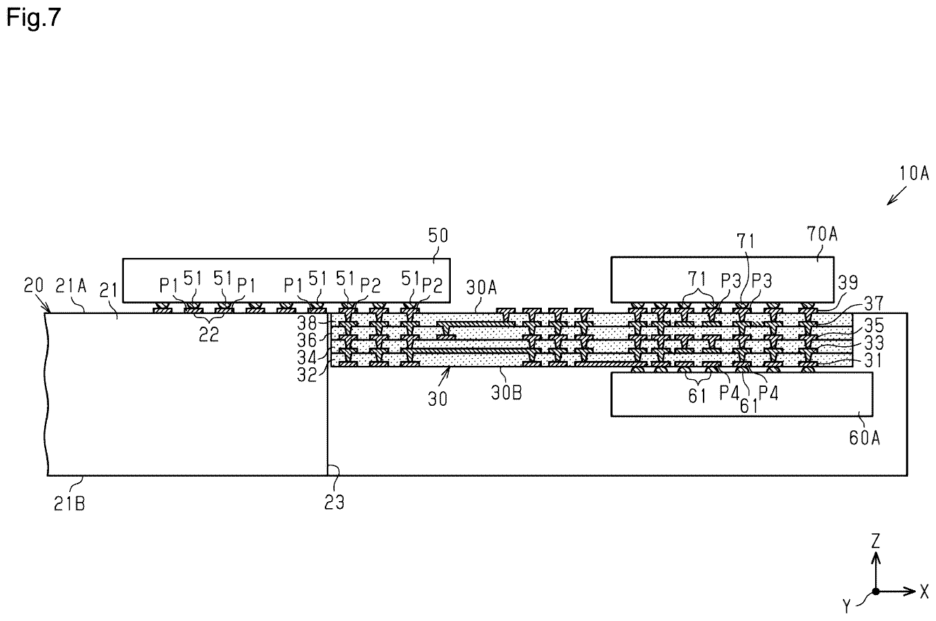

A second embodiment will now be described with reference to FIG. 7. The description hereafter will focus on differences from the first embodiment. The same reference numerals are given to those components that are the same as the corresponding components illustrated in FIGS. 1 to 6. Such components will not be described in detail.

### Overall Structure of Semiconductor Device 10A

As illustrated in FIG. 7, a semiconductor device 10A includes the first substrate 20, the second substrate 30, the first semiconductor element 50, a second semiconductor element 70A, and a third semiconductor element 60A. The first semiconductor element 50 is mounted on the upper surface 21A of the first substrate 20 and the upper surface 30A of the second substrate 30 so as to extend across the first substrate 20 and the second substrate 30. The second semiconductor element 70A is mounted on the upper surface 30A of the second substrate 30. The third semiconductor element 60A is mounted on the lower surface 30B of the second substrate 30.

In the second embodiment, the second substrate 30 is elongated in the X-axis direction. The wiring layers 31, 33, 35, 37, and 39 of the second substrate 30 include a wiring pattern in which wirings, lands, and the like extend in the planar direction (X-axis direction).

### Structure of First Semiconductor Element 50

The first semiconductor element 50 is an LSI including an electrical circuit for processing signals. The first semiconductor element 50 generates more heat than the second semiconductor element 70A. The first semiconductor element 50 generates more heat than the third semiconductor element 60A. The first semiconductor element 50, which generates a large amount of heat, is mounted on the upper surface 21A of the first substrate 20 and the upper surface 30A of the second substrate 30 to connect the first substrate 20 and the second substrate 30. The first semiconductor element 50 is flip-chip mounted on the upper surface 21A of the first substrate 20 and flip-chip mounted on the upper surface 30A of the second substrate 30.

### Structure of Second Semiconductor Element 70A

The second semiconductor element 70A is, for example, an electrical IC for driving an optical circuit and is similar to the third semiconductor element 70 illustrated in FIG. 1. The second semiconductor element 70A has a smaller thermal resistance than the first semiconductor element 50. In one example, the second semiconductor element 70A has a lower thermal resistance than the first semiconductor element 50 and is vulnerable to heat. The second semiconductor element 70A is flip-chip mounted on the upper surface 30A of the second substrate 30. The second semiconductor element 70A is electrically connected to the third connection pads P3 of the second substrate 30 by the bumps 71 formed on the circuit formation surface (lower surface) of the second semiconductor element 70A.

The second semiconductor element 70A is, for example, located on the same plane as the first semiconductor element 50. The second semiconductor element 70A is spaced apart by a predetermined distance in the X-axis direction from the first semiconductor element 50. For example, the distance in the X-axis direction between the first semiconductor element 50 and the second semiconductor element 70A is greater than the distance in the X-axis direction between the wall surface of the through hole 23 and the side surface of the second substrate 30. For example, the distance in the X-axis direction between the first semiconductor element 50 and the second semiconductor element 70A is smaller than the dimension of the second semiconductor element 70A in the X-axis direction.

### Structure of Third Semiconductor Element 60A

The third semiconductor element 60A is, for example, a photonic IC including an optical circuit and is similar to the second semiconductor element 60 illustrated in FIG. 1. The third semiconductor element 60A has a smaller thermal resistance than the first semiconductor element 50. In one example, the third semiconductor element 60A has a lower thermal resistance than the first semiconductor element 50 and is vulnerable to heat. The third semiconductor element 60A has a smaller thermal resistance than the second semiconductor element 70A. Among the first semiconductor element 50, the second semiconductor element 70A, and the third semiconductor element 60A, the third semiconductor element 60A has the smallest thermal resistance and is most vulnerable to heat.

The third semiconductor element 60A, which is vulnerable to heat, is mounted on the lower surface 30B of the second substrate 30 at the opposite side of the upper surface 30A where the first semiconductor element 50 is mounted. The third semiconductor element 60A is flip-chip mounted on the lower surface 30B of the second substrate 30. The third semiconductor element 60A is electrically connected to the fourth connection pads P4 of the second substrate 30 by the bumps 61 formed on the circuit formation surface (upper surface) of the third semiconductor element 60A. Further, the third semiconductor element 60A overlaps the second semiconductor element 70A but not the first semiconductor element 50 in plan view. Thus, the third semiconductor element 60A, which is vulnerable to heat, and the first semiconductor element 50, which generates a large amount of heat, are spaced apart by a predetermined distance. Accordingly, the third semiconductor element 60A is not affected by the heat generated by the first semiconductor element 50. Further, the third semiconductor element 60A is arranged proximate to the second semiconductor element 70A.

The end (right end in FIG. 7) of the third semiconductor element 60A in the X-axis direction projects further in the X-axis direction (right direction in FIG. 7) from, for example, the end surface (right end surface in FIG. 7) the second substrate 30 in the X-axis direction. In other words, the right end of the third semiconductor element 60A in the X-axis direction does not overlap the second substrate 30 in plan view. Such end of the third semiconductor element 60A in the X-axis direction is, for example, optically coupled to a light transmission path such as an optical fiber (not illustrated).

In addition to advantages (1-1) to (1-3) and (1-5) to (1-8), the second embodiment has the advantage described below.

(2-1) The third semiconductor element 60A, which is vulnerable to heat, overlaps the second semiconductor element 70A but not the first semiconductor element 50, which generates a large amount of heat. Thus, the third semiconductor element 60A, which is vulnerable to heat, and the first semiconductor element 50, which generates a large amount of heat, are spaced apart by a predetermined distance. Accordingly, the third semiconductor element 60A is not affected by the heat generated by the first semiconductor element 50.

### Other Embodiments

The above embodiments may be modified as described below. The above-described embodiments and the modified examples described below may be combined as long as there is no technical contradiction.

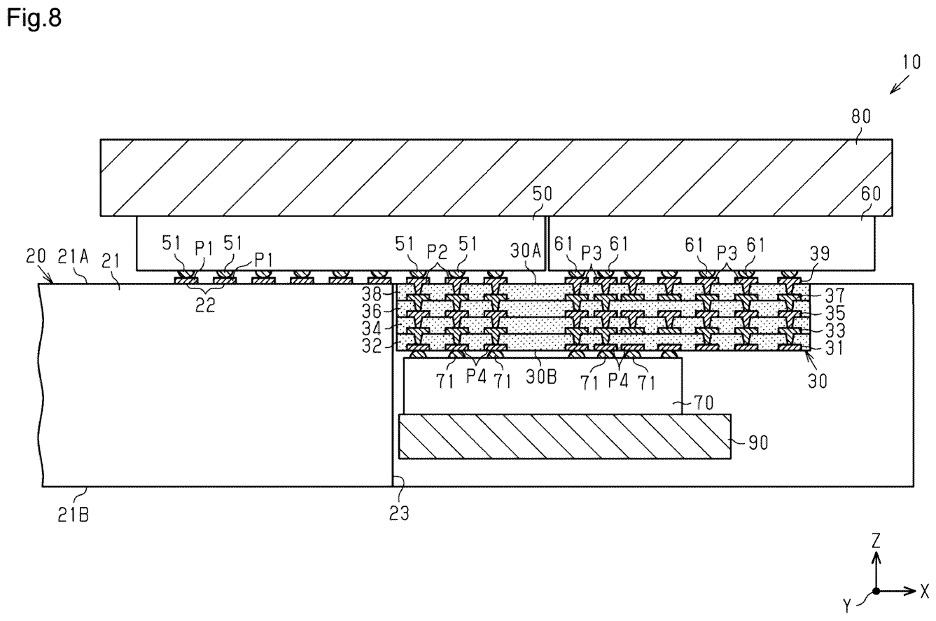

As illustrated in FIG. 8, a first heatsink 80 may be mounted on the upper surface of the first semiconductor element 50. The first heatsink 80 is thermally coupled to the first semiconductor element 50. In the present modified example, the first heatsink 80 is also thermally coupled to the second semiconductor element 60. The first heatsink 80 is bonded by an adhesive layer (not illustrated) to the upper surface of the first semiconductor element 50 and the upper surface of the second semiconductor element 60. The adhesive layer may be, for example, an epoxy-based, polyimide-based, or silicone-based thermosetting adhesive or a thermal interface material (TIM). The first heatsink 80 is also referred to as a heat spreader. The first heatsink 80 functions to dissipate the heat generated by the first semiconductor element 50.

In this structure, the first heatsink 80 efficiently dissipates the heat generated by the first semiconductor element 50. Further, the first heatsink 80 efficiently dissipates the heat generated by the second semiconductor element 60. This suppresses temperature increases in the first semiconductor element 50 and the second semiconductor element 60.

As illustrated in FIG. 8, a second heatsink 90 may be mounted on the lower surface of the third semiconductor element 70. The second heatsink 90 is thermally coupled to the third semiconductor element 70. The second heatsink 90 is bonded by an adhesive layer (not illustrated) to the lower surface of the third semiconductor element 70. The adhesive layer may be, for example, an epoxy-based, polyimide-based, or silicone-based thermosetting adhesive or a thermal interface material. The second heatsink 90 is also referred to as a heat spreader. The second heatsink 90 functions to dissipate the heat generated by the third semiconductor element 70. The lower surface of the second heatsink 90 is, for example, located upward from the lower surface 21B of the first substrate 20. In other words, the thickness of the first substrate 20 in the present modified example is greater than the sum of the thickness of the second substrate 30, the thickness of the third semiconductor element 70, and the thickness of the second heatsink 90.

In this structure, the second heatsink 90 efficiently dissipates the heat generated by the third semiconductor element 70. This limits temperature increases in the third semiconductor element 70.

The first heatsink 80 and the second heatsink 90 allow the heat dissipation path of the first semiconductor element 50 to be separate from the heat dissipation path of the third semiconductor element 70. Thus, heat is efficiently dissipated from the first semiconductor element 50 and the third semiconductor element 70 regardless of the heat dissipating situation of each element.

In the same manner as the modified example illustrated in FIG. 8, the first heatsink 80 and the second heatsink 90 may be mounted on the semiconductor device 10A.

In the modified example illustrated in FIG. 8, the first heatsink 80 may be mounted on only the upper surface of the first semiconductor element 50. That is, the first heatsink 80 may be modified so that it is not mounted on the upper surface of the second semiconductor element 60. In this case, a heatsink differing from the first heatsink 80 may be mounted on the upper surface of the second semiconductor element 60.

In the modified example illustrated in FIG. 8, one of the first heatsink 80 and the second heatsink 90 may be omitted.

In each of the above embodiments, an accommodation portion that accommodates the second substrate 30 is defined by the through hole 23 extending through the first substrate 20 in the thickness direction. This, however, is not a limitation. For example, the accommodation portion that accommodates the second substrate 30 may be a recess including a bottom surface. In this case, the accommodation portion is, for example, recessed from the upper surface 21A toward the lower surface 21B in the substrate body 21 of the first substrate 20. In this case, the accommodation portion does not extend through the first substrate 20 in the thickness direction.

In each of the above embodiments, the through hole 23 is a notch that is formed in one side of the first substrate 20 to open in the X-axis direction but not necessarily a notch. For example, the through hole 23 may be formed so as not to open in the X-axis direction.

In each of the above embodiments, the through hole 23 may be omitted. In this case, for example, the second substrate 30 may project outward from any side surface of the first substrate 20.

In the second substrate 30 of each embodiment, the number of wiring layers and the wiring layout may be changed. In the same manner, the number of insulation layers in the second substrate 30 may be changed.

In each of the above embodiments, the second substrate 30 is a coreless substrate but does not have to be a coreless substrate. For example, the second substrate 30 may be a wiring substrate that is a cored substrate.

In each of the above embodiments, the second substrate 30 may be reversed upside down. In such a second substrate 30, the second connection pads P2 and the third connection pads P3 are arranged on the wiring layer 31, and the fourth connection pads P4 are arranged on the wiring layer 39.

In each of the above embodiment, the first semiconductor element 50, the second semiconductor elements 60 and 70A, and the third semiconductor elements 70 and 60A may be mounted in any manner (flip-chip mounting, wire-bonding mounting, solder mounting, or a combination of such types of mounting).

In the first embodiment, the locations of the first semiconductor element 50, the second semiconductor element 60, and the third semiconductor element 70 may be changed. For example, the third semiconductor element 70 may be mounted on the upper surface 30A of the second substrate 30, and the second semiconductor element 60 may be mounted on the lower surface 30B of the second substrate 30.

In the above embodiments, the semiconductor devices 10 and 10A are optical semiconductor devices. The semiconductor devices 10 and 10A may be semiconductor devices other than optical semiconductor devices. For example, the first semiconductor element 50, the second semiconductor elements 60 and 70A, and the third semiconductor elements 70 and 60A may be semiconductor elements other than the above-described LSI for processing signals, photonic IC, and electrical IC for driving an optical circuit. The first semiconductor element 50, the second semiconductor elements 60 and 70A, and the third semiconductor elements 70 and 60A may each be, for example, a logic chip such as a central processing unit (CPU) chip or a graphics processing unit (GPU) chip. Further, the first semiconductor element 50, the second semiconductor elements 60 and 70A, and the third semiconductor elements 70 and 60A may each be, for example, a memory chip such as a dynamic random access memory (DRAM) chip or a flash memory chip.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a first substrate;
a second substrate spaced apart from the first substrate;
a first semiconductor element mounted on an upper surface of the first substrate and an upper surface of the second substrate so as to extend across the first substrate and the second substrate;
a second semiconductor element mounted on the upper surface of the second substrate; and
a third semiconductor element mounted on a lower surface of the second substrate,
wherein the third semiconductor element overlaps the second semiconductor element in plan view.

2. The semiconductor device according to claim 1, wherein the third semiconductor element overlaps the first semiconductor element in plan view.

3. The semiconductor device according to claim 1, wherein the third semiconductor element does not overlap the first semiconductor element in plan view.

4. The semiconductor device according to claim 3, wherein
the first semiconductor element is configured to generate more heat than each of the second semiconductor element and the third semiconductor element, and
the third semiconductor element has a thermal resistance that is smaller than that of the first semiconductor element.

5. The semiconductor device according to claim 4, wherein
the third semiconductor element is a photonic integrated circuit including an optical circuit,
the second semiconductor element is an electrical integrated circuit including an electrical circuit for driving the optical circuit, and
the first semiconductor element is a large scale integration including an electrical circuit for signal processing.

6. The semiconductor device according to claim 1, wherein
the second semiconductor element is a photonic integrated circuit including an optical circuit,
the third semiconductor element is an electrical integrated circuit including an electrical circuit for driving the optical circuit, and
the first semiconductor element is a large scale integration including an electrical circuit for signal processing.

7. The semiconductor device according to claim 1, wherein the second substrate does not overlap the first substrate in plan view.

8. The semiconductor device according to claim 7, wherein
the first substrate includes a through hole extending through the first substrate in a thickness direction, and
the second substrate is arranged inside the through hole.

9. The semiconductor device according to claim 8, wherein the through hole is a notch.

10. The semiconductor device according to claim 1, wherein
the upper surface of the second substrate is coplanar with the upper surface of the first substrate, and
the lower surface of the second substrate is located below a lower surface of the first substrate.

11. The semiconductor device according to claim 1, wherein
the second substrate is a coreless substrate, and
the first substrate has a thickness that is greater than a total of a thickness of the second substrate and a thickness of the third semiconductor element.

12. The semiconductor device according to claim 1, wherein
the first substrate includes a through hole extending through the first substrate in a thickness direction and accommodating the second substrate,
the first semiconductor element faces and is separated from the second semiconductor element in a first direction in plan view,
the second substrate includes a first end surface facing a wall surface of the through hole in the first direction and a second end surface at an opposite side of the first end surface,
the first end surface of the second substrate overlaps the first semiconductor element in plan view, and
the second end surface of the second substrate overlaps the second semiconductor element in plan view.

13. The semiconductor device according to claim 12, wherein
the first semiconductor element projects outward from the first end surface of the second substrate in the first direction,
the second semiconductor element projects outward from the second end surface of the second substrate in the first direction, and
a dimension of the second substrate in the first direction is less than a total of a dimension of the first semiconductor element in the first direction and a dimension of the second semiconductor element in the first direction.

14. The semiconductor device according to claim 1, further comprising:
a first heatsink mounted on an upper surface of the first semiconductor element, and
a second heatsink mounted on a lower surface of the third semiconductor element.
